(19) United States
(12) Patent Application Publication
(10) Pub. No.: US 2015/0181774 A1
(43) Pub. Date: Jun. 25, 2015

(54) REDUCING CROSSTALK IN BOARD-TO-BOARD ELECTRONIC COMMUNICATION

(71) Applicant: Pi-Coral, Inc., San Jose, CA (US)

(72) Inventors: Albert G. Baetz, Dayton, NJ (US); Donpaul C. Stephens, Houston, TX (US)

(21) Appl. No.: 14/639,605

(22) Filed: Mar. 5, 2015

Related U.S. Application Data
(63) Continuation of application No. PCT/US2013/058645, filed on Sep. 6, 2013.
(60) Provisional application No. 61/697,711, filed on Sep. 6, 2012.
(60) Provisional application No. 61/798,395, filed on Mar. 15, 2013.
(60) Provisional application No. 61/798,800, filed on Mar. 15, 2013.

(51) Int. Cl. H05K 9/00; H05K 7/14

(52) U.S. Cl. CPC H05K 9/0062; H05K 7/1424

(57) ABSTRACT

A technique for communicating electronic signals between circuit boards includes separating conductive traces for carrying TX signals from those for carrying RX signals and conveying the separated TX and RX signals between circuit boards on respective sets of distinct midplane circuit board layers. The layers may be distinct circuit board layers on a single board or distinct layers on different boards.

### CROSS-REFERENCE TO RELATED APPLICATIONS

This is a continuation of PCT/US2013058645, filed Sep. 6, 2013, which claims priority to U.S. provisional application No. 61/697,711, filed Sep. 6, 2012, U.S. provisional application No. 61/798/395, filed Mar. 15, 2013, and U.S. provisional application No. 61/798,800, filed Mar. 15, 2013. The contents and teachings of these related applications are incorporated herein by reference as if set forth explicitly.

### BACKGROUND

Many diverse electronic applications require the use of multiple circuit board assemblies. The circuit board assemblies are commonly housed within one or more chassis. The chassis may be free-standing or installed in racks. Data centers and other facilities typically include many racks, each holding multiple chassis. The racks may be provided together in rooms, which may be environmentally controlled for temperature and humidity.

Within racks, it is common to convey electronic signals between different circuit board assemblies via backplanes or midplanes. In a typical scenario, a first set of circuit board assemblies plugged into one end of a chassis communicates electronic signals with a second set of circuit board assemblies plugged into an opposite end of the chassis via a midplane disposed between the first set of circuit board assemblies and the second set of circuit board assemblies. In some examples, the electronic signals are provided as differential signals. As is known, differential signals each include two parts, sometimes referred to as “legs.” A voltage or current between the legs indicates a digital value of the differential signal. Typically, as the digital value of a differential signal is changed, the polarity of the difference in voltage or current between the different legs is reversed. The legs of differential signals are typically routed on circuit boards and through systems side-by-side, such that noise coupled to one leg also tends to couple to the other, with the two legs being similarly affected but their difference being largely unaffected.

### SUMMARY

Unfortunately, crosstalk can impair digital communication in electronic systems, even when differential signals are used. For example, many systems employ differential modules and/or devices that both send and receive differential signals. Even though differential signals provide inherent noise immunity when their legs are routed side-by-side, it is often difficult to avoid crosstalk between differential signals transmitted from a circuit board and differential signals received by the same circuit board. Systems are particularly susceptible to crosstalk induced when transmit (TX) signals electrostatically couple to receive (RX) signals because RX signals tend to be much smaller in amplitude than TX signals. It is not uncommon for a device asserting a high amplitude TX signal to disturb a low amplitude RX signal on the same device. The offending disturbance may occur anywhere in the transmission paths, such as between circuit board traces, on connectors, or on backplanes or midplanes, and, if severe, may cause communication errors between circuit boards. System designers seek to minimize crosstalk by carefully providing space between transmit (TX) and receive (RX) signals and by providing electrostatic shields in the form of ground planes and power planes, but these measures can lead to very complex and expensive circuit boards with many layers.

In contrast with conventional designs, an improved technique for communicating electronic signals between circuit boards includes separating conductive traces for carrying TX signals from those for carrying RX signals and conveying the separated TX and RX signals between circuit boards on respective sets of distinct midplane circuit board layers. The layers may be distinct circuit board layers on a single board or distinct layers on different boards. For example, one midplane circuit board conveys TX signals generated on a first board between the first board and a second board, whereas another midplane circuit board conveys RX signals received by the first board between the first board and the second board. Crosstalk between RX and TX signals is thus greatly reduced or eliminated.

Certain embodiments are directed to a system for conveying electronic signals between card assemblies. The system includes a first card assembly having (i) a circuit board that separates multiple conductive traces for carrying transmit (TX) signals generated by the first card assembly from multiple conductive traces for carrying receive (RX) signals received by the first card assembly, (ii) a first connector electrically coupled to the multiple conductive traces for carrying the TX signals, and (iii) a second connector electrically coupled to the multiple conductive traces for carrying the RX signals. The system further includes a midplane assembly. The midplane assembly has (i) a first connector coupled to the first connector of the first card assembly, (ii) a second connector coupled to the second connector of the first card assembly, (iii) a first set of midplane circuit board layers coupled to the first connector of the midplane assembly to convey the TX signals between the first card assembly and a second card assembly, and (iv) a second set of midplane circuit board layers, distinct from the first set of midplane circuit board layers and coupled to the second connector of the midplane assembly to convey the RX signals between the first card assembly and the second card assembly. The system is thus constructed and arranged to convey TX signals and RX signals between the first card assembly and the second card assembly on distinct sets of midplane circuit board layers.

Other embodiments are directed to a method of conveying electronic signals between a first card assembly and a second card assembly via a midplane assembly. The method includes physically separating multiple conductive traces for carrying transmit (TX) signals generated by the first card assembly from multiple conductive traces for carrying receive (RX) signals received by the first card assembly, including (i) providing the conductive traces for carrying the TX signals in electrical connection with a first connector of the first card assembly and (ii) providing the conductive traces for carrying the RX signals in electrical connection with a second connector of the first card assembly. The method further includes electrically coupling the conductive traces for carrying the TX signals at the first connector of the first card assembly to a first connector of the second card assembly via a first set of midplane circuit board layers of the midplane assembly. The method still further includes electrically coupling the conductive traces for carrying the RX signals at the second connector of the first card assembly to a second connector of the second card assembly via a second set of midplane circuit board layers of the midplane assembly distinct from the first set of midplane circuit board layers of the midplane assembly.

### BRIEF DESCRIPTION OF THE SEVERAL VIEWS OF THE DRAWINGS

The foregoing and other features and advantages will be apparent from the following description of particular embodiments of the invention, as illustrated in the accompanying drawings, in which like reference characters refer to the same parts throughout the different views. The drawings are not necessary to scale, emphasis instead being placed upon illustrating the principles of various embodiments of the invention. In the accompanying drawings,

FIG. 1 is an isometric view of an example system in which embodiments of the invention can be practiced;

FIG. 2 is an isometric view of system of FIG. 1 from a different perspective;

FIG. 3 is another isometric view of the example system of FIG. 1, but with a circuit board assemblies at the rear of the chassis removed to reveal midplane connectors;

FIG. 4 is an isometric view of an example midplane assembly, which includes two midplane boards fastened together;

FIG. 5 is a simplified side view of a portions of the system of FIG. 1 arranged for separating TX and RX signals on a first card assembly and communicating them with a second card assembly via respective distinct sets of midplane circuit board layers;

FIG. 6 is a simplified side view of a portions of the system of FIG. 1 arranged for separating TX and RX signals on a first card assembly and communicating them with a second card assembly via respective midplane circuit boards;

FIG. 7 is a simplified side view showing an array of first card assemblies coupled to an array of second card assemblies via a pair of midplane boards, where a first of the midplane boards conducts TX signals generated in the array of first card assemblies and a second of the midplane boards conducts RX signals received by the array of first card assemblies; and

FIG. 8 is a flowchart showing an example process for communicating signals between different circuit boards of an electronic system.

### DETAILED DESCRIPTION OF THE INVENTION

Embodiments of the invention will now be described. It is understood that such embodiments are provided by way of example to illustrate various features and principles of the invention, and that the invention hereof is broader than the specific example embodiments disclosed.

An improved technique for communicating electronic signals between circuit boards includes separating conductive traces for carrying TX signals from those for carrying RX signals and conveying the separated TX and RX signals between circuit boards on respective sets of distinct midplane circuit board layers.

### Example System Environment:

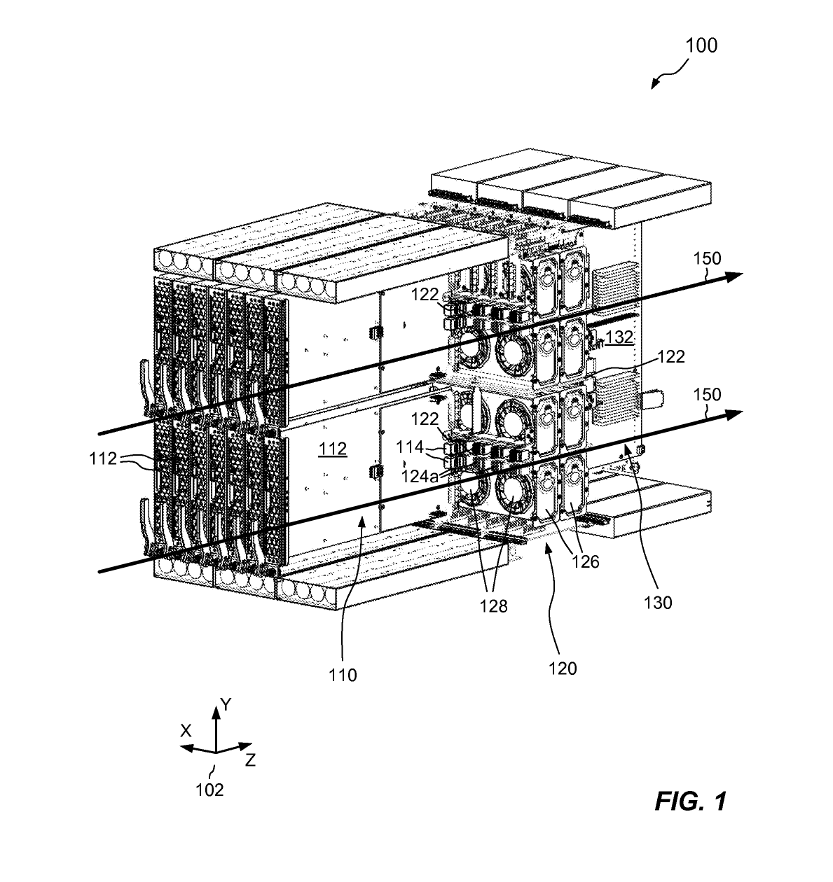

FIGS. 1-3 show various views of an example system in which the improved technique hereof may be practiced. A description of the particular improvements hereof begins at the section below entitled “Crosstalk Reduction.”

Beginning with FIG. 1, it is seen that an example system is realized in the form of a chassis 100 that includes a first region 110, a second region 120, and a third region 130. The regions 110, 120, and 130 are spaces within the chassis 100 for containing various components. As shown, the first region 110 includes a first array of one or more circuit board assemblies (PCAs) 112, the second region 120 includes a second array of one or more PCAs 122 (e.g., midplane boards, as best seen in FIG. 6), and the third region 130 includes a third array of one or more PCAs 132.

A legend 102 indicates relative orientation in mutually orthogonal X-Y-Z space. The PCAs 112 and 132 can thus be seen as oriented parallel to a Y-Z plane of the X-Y-Z space, while the PCAs 122 can be seen as oriented parallel to an X-Z plane of the X-Y-Z space. The first, second, and third regions 110, 120, and 130 are seen to extend successively back in a positive Z direction.

In the particular example shown, the first array of PCAs 112 are provided as half-height PCAs (i.e., they occupy half the vertical height for housing PCAs in the region 110). However, this is merely an example, as the PCAs may alternatively occupy some other fraction of the total height or the entire height. In some embodiments, the PCAs in the upper half of the first region 110 can be regarded as yet another array of PCAs, which interconnects with other components of the chassis 100 in a similar way to the first array of PCAs 112.

The second region 120 is seen to further include multiple fan trays 126, with each fan tray 126 including multiple fans 128. A total of eight fan trays 126 are shown; however, any suitable number may be provided. The fan trays 126 are positioned among the PCAs 122 within the second region 120. For example, two fan trays 126 are shown disposed between upper and lower pairs of PCAs 122.

In the example shown, six PCAs 122 are provided in second region 120. Any suitable number of PCAs 122 may be included, however, as best suited for the particular implementation. The PCAs 122 may be provided in pairs, as shown (see FIG. 6), or the PCAs 122 may be provided separately. In some examples, additional PCAs 122 are provided at the bottom of the region 120 (e.g., beneath the lower-most fan tray 126), at the top of the region 120 (e.g., above the upper-most fan tray 126), and/or at some other vertical location.

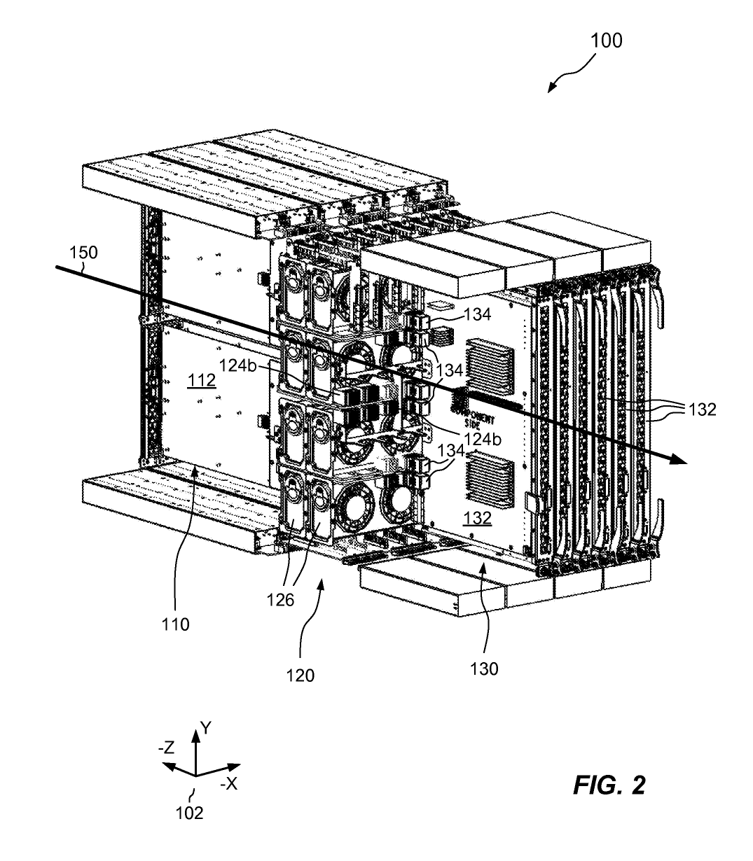

With the orientations of PCAs 112, 122, and 132 as shown, the PCAs 122 in the second region 120 can be seen to contact the PCAs 112 and 132 in the first and third regions 110 and 130 edge-to-edge and orthogonally, such that each of the PCAs 122 cuts across multiple PCAs 112 and 132 and forms connections therewith. For example, the PCAs 112 in the first region 110 include connectors 114, which engage with connectors 124a on the PCAs 122. Similarly, the PCAs 132 include connectors 134 (best seen in FIG. 2), which engage connectors 124b on the PCAs 122. The array of PCAs 122 can thus be regarded as forming a midplane, and the individual PCAs 122 can be regarded as midplane boards. PCAs 112 and 132 can be inserted along card guides into designated locations within the chassis 100, with the connectors 114 engaging the connectors 124a on the PCAs 122 (midplane boards) and the connectors 134 engaging connectors 124b on the PCAs 122.

The PCAs 122 typically include conductive traces, ground planes, power planes, etc., for conveying electrical signals between different PCAs. Different implementations have different requirements, however, and the PCAs 122 can be provisioned with traces, planes, and even electrical components as needed to suit the requirements of particular use cases. In one example, the PCAs 122 include conductive traces that establish electrical connections between the PCAs 112 in the first region 110 and the PCAs 132 in the third region 130.

Because the PCAs 122 have a length, signal routing is often more easily achieved than when using conventional backplanes and midplanes, since the entire length of the PCAs 122 may be available for signal routing. In some examples, the PCAs 122 may be made longer or shorter, based on routing requirements, desired numbers of PCA layers, available space, cost, and other factors. The length of PCAs 122 thus provides an additional degree of freedom, which designers may consider when developing chassis for particular applications.

With the arrangement shown, it is also evident that airflow 150 can be established in the Z direction of the X-Y-Z space without any substantial bends or turns. For example, air enters the first region 110 of the chassis 100, passes among and between the PCAs 112 in the first region 110, passes through the fans 128 in the second region 120, and passes among and between the PCAs 132 in the third region 130, before exiting the third region 130 at the rear of the chassis 100. Because all PCAs 112, 122, and 132 are oriented parallel to the direction of airflow 150 (i.e., parallel to the Z-axis), air passes over and through the PCAs 112, 122, and 132 substantially unimpeded. It should be understood that electronic parts, connectors, heatsinks, fan frames, and other components may interfere slightly with airflow 150 and thus alter the flow of packets of air on a small scale. Such packets of air may thus take minor turns as they pass around and between components of the chassis 100. Obstructions like these are expected and desired, however, as they promote cooling of components. But airflow 150 when viewed in the aggregate maintains a straight line course as it passes from the front of the chassis 100 to the back. Although the direction of airflow 150 is shown as extending front-to-back, example embodiments work equally well with the direction of airflow 150 reversed.

The chassis 100 provides a number of distinct advantages over conventional chassis. For example, because airflow 150 follows a straight line course, there is no need for the fans 128 to force large amounts of air around corners. Thus, the fans 128 can be made significantly smaller and/or lower power, and/or fewer fans can be provided. The chassis 100 can thus consume less electricity than conventional chassis. Further, the direct path of airflow 150 avoids the need for intake and/or outlet plena, thus allowing the chassis 100 to be made smaller than conventional chassis. Further still, the PCAs 122 used as midplane/backplane boards can often be manufactured less expensively than conventional backplane/midplane cards, with fewer layers and fewer routing constraints. Together, these factors can significantly reduce initial cost of the chassis 100. They can also reduce operating costs and failure rates of the chassis 100 as compared with conventional designs.

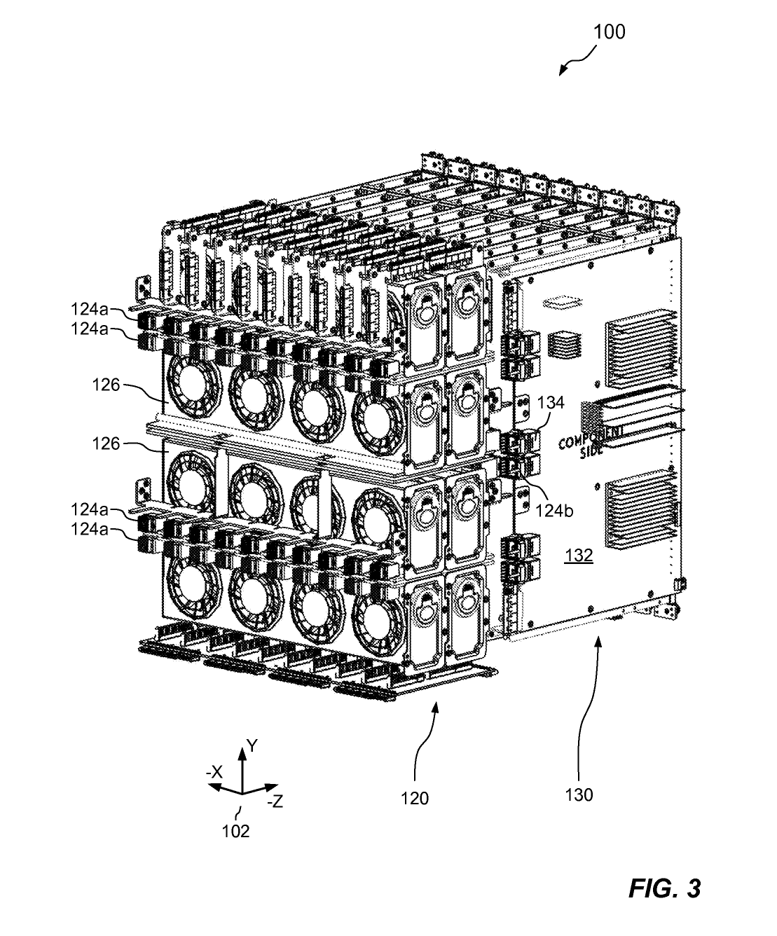

Other figures show additional views of the chassis 100. FIG. 2 shows the chassis 100 from the rear, providing a view of connectors 124b on the PCAs 122 and their mating with connectors 134 on the PCAs 132. FIG. 3 shows the chassis 100 with the first array of PCAs 112 removed, thus also exposing connectors 124a on the PCAs 122.

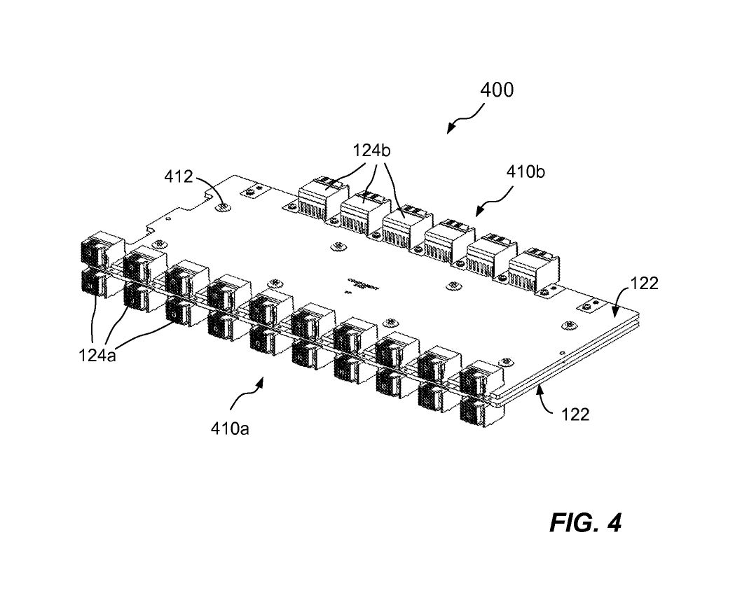

FIG. 4 shows an example assembly 400 that includes two PCAs 122. Each of the PCAs 122 shown in FIG. 4 has a first array of connectors 124a at a first end 410a, which connectors 124a are arranged to engage with connectors 114 (FIG. 1) on the PCAs 112 in the first region 110. Each of the PCAs 122 also has a second array of connectors 124b at a second end 410b, which connectors 124b are arranged to engage connectors 134 on the PCAs 132 in the third region 130 (FIG. 2). The two PCAs 122 shown in FIG. 4 are fastened together, e.g., using screws 412, adhesive, or some other type of fastener or material. In some examples, an insulative layer is interposed between the PCAs 122 to prevent short circuits and/or to fill air gaps. In a further example, a metal layer (not shown) is placed between the PCAs 122. The metal layer is connected or AC-coupled to an electrical ground of the chassis 100 to provide an electrostatic shield between the two PCAs 122 shown in FIG. 4. One or more insulative layers may also be provided to prevent the PCAs 122 from shorting to the shield.

In the example shown in FIG. 4, the two PCAs 122 are constructed substantially as mechanical mirror images of each other. The connectors 124a and 124b on the top PCA face up (i.e., in the positive Y direction), whereas the connectors 124a and 124b on the bottom PCA face down (i.e., in the negative Y direction), opposite the direction of connectors on the top PCA.

Providing PCAs 122 in the form of assemblies 400 makes efficient use of space in the second region 120 and helps to minimize resistance to airflow 150. It should be understood, however, that assemblies of PCAs 122 can be constructed in other ways than that shown in FIG. 4. For example, PCAs 122 with similar geometry (not mirror images) can be stacked one on top of the other in any suitable arrangement. In addition, PCAs 122 may be provided individually, separate from any assembly of multiple PCAs 122. Further, although the assembly 400 is seen to include two PCAs 122, other assemblies can be constructed that include a greater number of PCAs. The example shown is merely illustrative.

### Crosstalk Reduction:

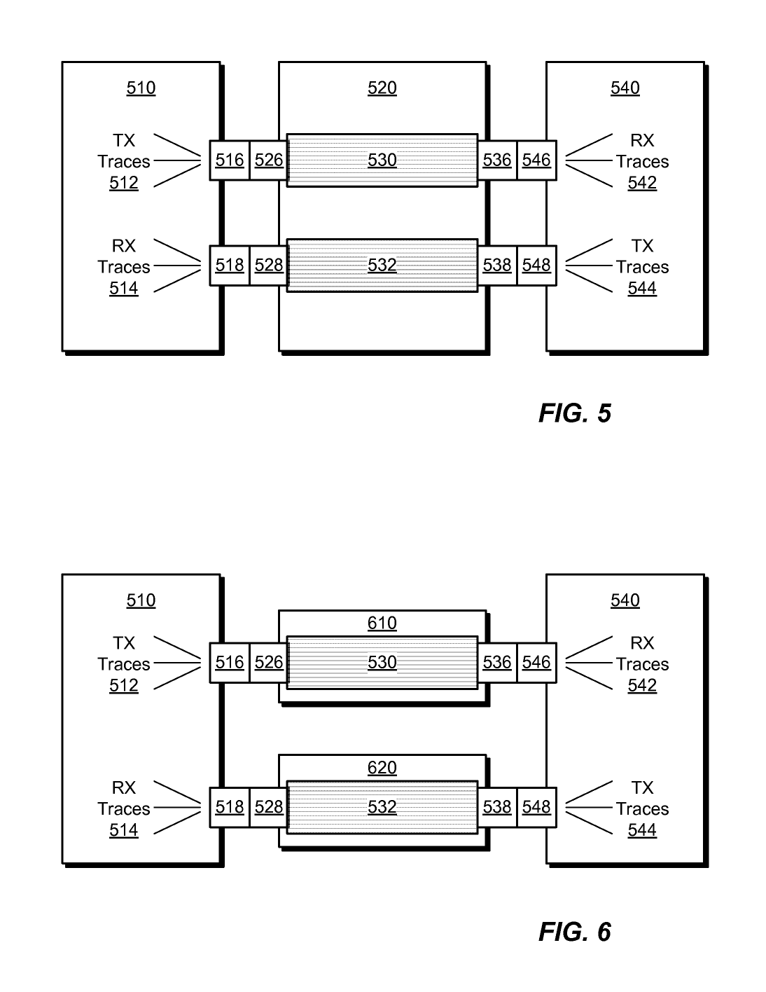

FIG. 5 shows an example arrangement for communicating electronic signals between a first card assembly 510 and a second card assembly 540 via a midplane assembly 520. In the illustrated example, the first card assembly 510 may be realized as any of the PCAs 112 provided in the first region of the chassis 100 and the second card assembly 540 may be realized as any of the PCAs 132 provided in the third region 130. The midplane assembly 520 may be realized as any of the PCAs 122 in the second region 120 or any combination of PCAs 122 in the second region 120.

As shown, the first card assembly 510 separates circuit board traces or wires 512 carrying TX signals from circuit board traces 514 carrying RX signals. For example, the first card assembly 510 may include many differential components, which provide differential TX outputs, receive differential RX inputs, and/or have both TX outputs and RX inputs. The separated TX traces 512 are conveyed to a first connector 516, and the separated RX traces 514 are conveyed to a second connector 518. In an example, the connectors 516 and 518 are high-density signal connectors and may be soldered or press-fit into the first card assembly 510 and are realized as specific examples of the connectors 114 (FIG. 1).

In a similar manner, the second card assembly 540 separates circuit board traces or wires 542 carrying RX signals from circuit board traces 544 carrying TX signals. For example, the second card assembly 540 also includes many differential components, which provide differential TX outputs, receive differential RX inputs, and/or have both TX outputs and RX inputs. The separated RX traces 542 are conveyed to a first connector 546 of the second card assembly 540, and the separated TX traces 544 are conveyed to a second connector 548 of the second card assembly 540. In an example, the connectors 546 and 548 are high-density signal connectors soldered or press-fit into the second card assembly 540 and are realized as specific examples of the connectors 134 (FIG. 2).

As shown in FIG. 5, the midplane assembly 520 includes a connector 526, which mates with or otherwise attaches to the connector 516 on the first card assembly. The midplane assembly 520 also includes a connector 536, which mates with or otherwise attaches to the connector 546 on the second card assembly 540. A first set of midplane layers 530 includes traces, wires, and/or planes that conduct signals from the connector 526 to the connector 536. The first set of midplane layers 530 thus conveys TX signals originating on the first card assembly 510 to the second card assembly 540, where they emerge from the connector 546 on the RX traces 542.

Also as shown in FIG. 5, the midplane assembly 520 includes a connector 528, which mates with or otherwise attaches to the connector 518 on the first card assembly. The midplane assembly 520 also includes a connector 538, which mates with or otherwise attaches to the connector 548 on the second card assembly 540. A second set of midplane layers 532 includes traces, wires, and/or planes that conduct signals from the connector 528 to the connector 538. The second set of midplane layers 532 thus conveys TX signals originating on the second card assembly 540 to the first card assembly 510, where they emerge from the connector 518 on the RX traces 514.

The first set of midplane layers 530 are physically distinct from the second set of midplane layers 532, so as to greatly reduce or eliminate crosstalk between the TX signals generated on the first card assembly 510 and the RX signals received by the first card assembly 510. The arrangement of FIG. 5 also reduces or eliminates crosstalk between the TX signals generated on the second card assembly 540 and the RX signals received by the second card assembly 540. With crosstalk thus reduced, communication errors between the first card assembly 510 and the second card assembly 540 are similarly reduced or eliminated.

In some examples, the first set of midplane layers 530 and the second set of midplane layers 532 are provided on separate layers of a single circuit board. For example, layers 1-4 may belong to the first set 530 whereas layers 6-9 may belong to the second set 532. Layer 5 may be provided as a ground plane to further separate the first set of layers 130 from the second set of layers 132 and to provide an electrostatic shield between the sets of layers.

FIG. 6 shows another example arrangement. Here, the first set of midplane layers 530 are provided on a first midplane board 610 and the second set of midplane layers 532 are provided on a second midplane board 620. The midplane boards 610 and 620 are physically distinct boards that each conduct signals between their respective connectors. Traces carrying TX and RX signals, as seen by either of the card assemblies 510 and 540, are thus physically separated from each other on different midplane boards 610 and 620, thus promoting a high degree of signal isolation. This high degree of isolation makes the arrangement of FIG. 6 particularly advantageous. In addition, midplane boards 610 and 620 can typically be manufactured inexpensively and without a large number of layers.

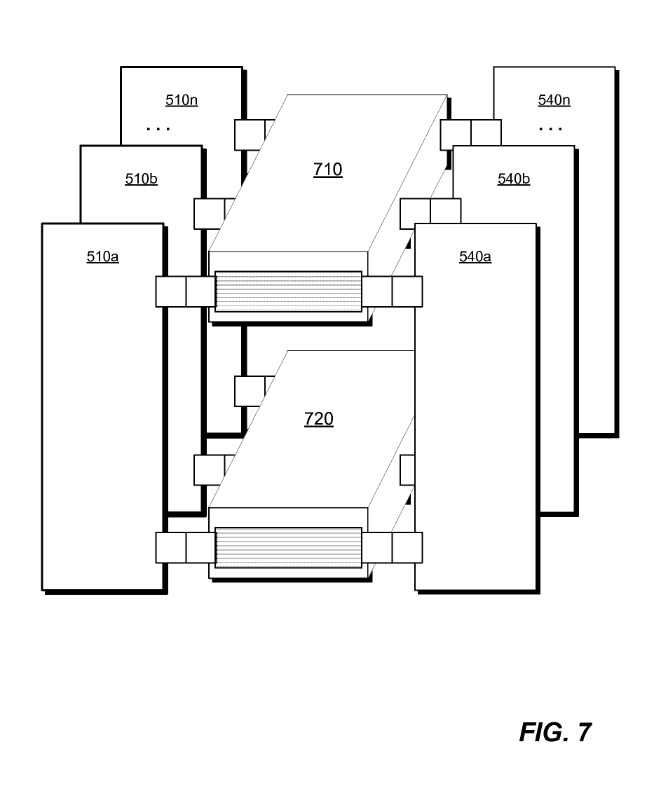

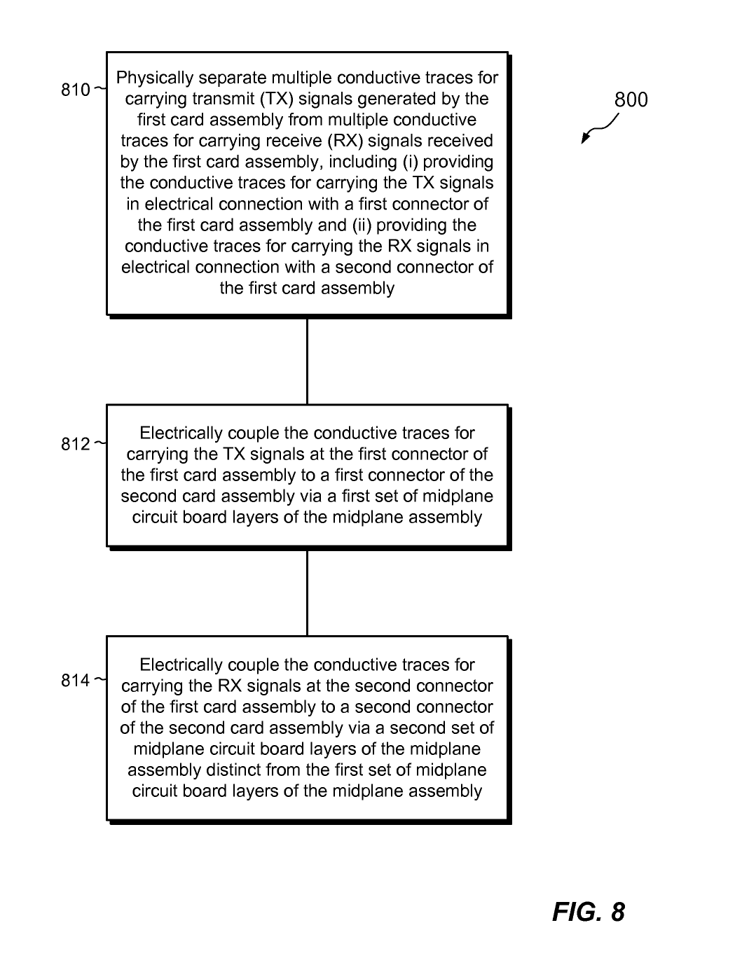

FIG. 7 shows an arrangement similar to FIG. 6, but projected across multiple card assemblies. Here, separate midplane boards 710 and 720 (similar to midplane boards 610 and 620, respectively) are seen to extend back to connect to an array of multiple first card assemblies 510a to 510n, like the card assembly 510, and to connect to an array of multiple second card assemblies 540a to 540n, like the card assembly 540. In an example, the first card assemblies 510a to 510n are realized with multiple PCAs 112, and the second card assemblies are realized with multiple PCAs 132. The midplane boards 710 and 720 are realized with a pair of PCAs 122. In a particular example, the midplane boards 710 and 720 are realized with the assembly 400 as shown in FIG. 4. In an example, the midplane board 710 conveys signals from TX traces 512 on each of the first card assemblies 510a-n to a respective one of the second card assemblies 540a-n (see FIG. 6). Similarly, the midplane board 720 conveys signals from TX traces 544 on each of the second card assemblies 540a-n to a respective one of the first card assemblies 510a-n.

FIG. 8 shows an example process 800 for conveying electronic signals between a first card assembly and a second card assembly via a midplane assembly. The process 800 may be carried out, for example, by the system of FIG. 1.

At step 810, multiple conductive traces for carrying transmit (TX) signals generated by the first card assembly are physically separated from multiple conductive traces for carrying receive (RX) signals received by the first card assembly. Separating the traces includes (i) providing the conductive traces for carrying the TX signals in electrical connection with a first connector of the first card assembly and (ii) providing the conductive traces for carrying the RX signals in electrical connection with a second connector of the first card assembly.

At step 812, the conductive traces for carrying the TX signals at the first connector of the first card assembly are electrically coupled to a first connector of the second card assembly via a first set of midplane circuit board layers of the midplane assembly.

At step 814, the conductive traces for carrying the RX signals at the second connector of the first card assembly are electrically coupled to a second connector of the second card assembly via a second set of midplane circuit board layers of the midplane assembly distinct from the first set of midplane circuit board layers of the midplane assembly

An improved technique has been described for communicating electronic signals between circuit boards. The technique includes separating conductive traces 512 for carrying TX signals from conductive traces 514 for carrying RX signals and conveying the separated TX and RX signals between circuit boards 510 and 540 on respective sets of distinct midplane circuit board layers 530 and 532. The layers 530 and 532 may be distinct circuit board layers on a single board or distinct layers on different boards (e.g., 610 and 620, or 710 and 720). Crosstalk between RX and TX signals is thus greatly reduced or eliminated.

As used throughout this document, the words “comprising,” “including,” and “having” are intended to set forth certain items, steps, elements, or aspects of something in an open-ended fashion. Also, as used herein and unless a specific statement is made to the contrary, the word “set” means one or more of something. Although certain embodiments are disclosed herein, it is understood that these are provided by way of example only and the invention is not limited to these particular embodiments. Further, the terms “front,” “back,” “top,” “bottom,” and so forth are used herein for convenient reference. It is understood, however, that the chassis 100 has no required orientation.

Having described certain embodiments, numerous alternative embodiments or variations can be made. For example, although the midplane assembly has been described as including one or more circuit boards that include conductive traces, other types of conductors may be used besides traces, such as cables or discrete wiring.

Further, although features are shown and described with reference to particular embodiments hereof, such features may be included and hereby are included in any of the disclosed embodiments and their variants. Thus, it is understood that features disclosed in connection with any embodiment are included as variants of any other embodiment. Those skilled in the art will therefore understand that various changes in form and detail may be made to the embodiments disclosed herein without departing from the scope of the invention.

What is claimed is:

1. A system for conveying electronic signals between card assemblies, comprising:
a first card assembly including (i) a circuit board that separates multiple conductive traces for carrying transmit (TX) signals generated by the first card assembly from multiple conductive traces for carrying receive (RX) signals received by the first card assembly, (ii) a first connector electrically coupled to the multiple conductive traces for carrying the TX signals, and (iii) a second connector electrically coupled to the multiple conductive traces for carrying the RX signals;
a midplane assembly including (i) a first connector coupled to the first connector of the first card assembly, (ii) a second connector coupled to the second connector of the first card assembly, (iii) a first set of midplane circuit board layers coupled to the first connector of the midplane assembly to convey the TX signals between the first card assembly and a second card assembly, and (iv) a second set of midplane circuit board layers, distinct from the first set of midplane circuit board layers and coupled to the second connector of the midplane assembly to convey the RX signals between the first card assembly and the second card assembly,
the system being thereby constructed and arranged to convey TX signals and RX signals between the first card assembly and the second card assembly on distinct sets of midplane circuit board layers.

2. The system of claim 1, wherein the second card assembly includes:
a circuit board that separates multiple conductive traces for carrying receive (RX) signals received by the second card assembly from multiple conductive traces for carrying transmit (TX) signals generated by the second card assembly;
a first connector electrically coupled to the multiple conductive traces for carrying the RX signals, and
a second connector electrically coupled to the multiple conductive traces for carrying the TX signals,
wherein the midplane assembly further includes (i) a third connector coupled to the first set of midplane circuit board layers and to the first connector of the second card assembly and (ii) a fourth connector coupled to the second set of midplane circuit board layers and to the second connector of the second card assembly.

3. The system of claim 2, wherein the TX signals generated by the first card assembly are each differential signals having two legs each, and wherein both legs of each of the TX signals generated by the first card assembly are conveyed between the first card assembly and the second card assembly via the first set of midplane circuit board layers.

4. The system of claim 3, wherein the RX signals received by the first card assembly are each differential signals having two legs each, and wherein both legs of each of the RX signals received by the first card assembly are conveyed between the first card assembly and the second card assembly via the second set of midplane circuit board layers.

5. The system of claim 3, wherein the first connector of the first card assembly is not electrically connected to any conductive traces for carrying any of the RX signals.

6. The system of claim 5, wherein the second connector of the first card assembly is not electrically connected to any conductive traces for carrying any of the TX signals.

7. The system of claim 6, wherein the midplane assembly includes a midplane board having multiple layers, the multiple layers of the midplane board including the first set of midplane circuit board layers and the second set of midplane circuit board layers.

8. The system of claim 4,
wherein the midplane assembly includes a first midplane board and a second midplane board,
wherein the first midplane board includes the first set of midplane circuit board layers, and
wherein the second midplane board includes the second set of midplane circuit board layers.

9. The system of claim 8, wherein the first card assembly is one of an array of first card assemblies and wherein the first midplane board includes a first plurality of connectors forming a first linear connector array for connecting with first connectors of respective card assemblies of the array of first card assemblies.

10. The system of claim 9, wherein the second card assembly is one of an array of second card assemblies and wherein the first midplane board includes a second plurality of connectors forming a second linear connector array for connecting with first connectors of respective card assemblies of the array of second card assemblies.

11. The system of claim 10, wherein the second midplane board includes a first plurality of connectors forming a first linear connector array for connecting with second connectors of respective card assemblies of the array of first card assemblies.

12. The system of claim 11, wherein the second midplane board includes a second plurality of connectors forming a second linear connector array for connecting with second connectors of respective card assemblies of the array of second card assemblies.

13. The system of claim 8, wherein the first midplane board and the second midplane board are fastened together to form an assembly.

14. A method of conveying electronic signals between a first card assembly and a second card assembly via a midplane assembly, comprising:
physically separating multiple conductive traces for carrying transmit (TX) signals generated by the first card assembly from multiple conductive traces for carrying receive (RX) signals received by the first card assembly, including (i) providing the conductive traces for carrying the TX signals in electrical connection with a first connector of the first card assembly and (ii) providing the conductive traces for carrying the RX signals in electrical connection with a second connector of the first card assembly;
electrically coupling the conductive traces for carrying the TX signals at the first connector of the first card assembly to a first connector of the second card assembly via a first set of midplane circuit board layers of the midplane assembly; and
electrically coupling the conductive traces for carrying the RX signals at the second connector of the first card assembly to a second connector of the second card assembly via a second set of midplane circuit board layers of the midplane assembly distinct from the first set of midplane circuit board layers of the midplane assembly.

15. The method of claim 14, wherein the TX signals are each differential signals having two legs each, wherein electrically coupling the conductive traces for carrying the TX signals at the first connector of the first card assembly to the first connector of the second card assembly includes electrically conveying both legs of each of the TX signals from the first connector of the first card assembly to the first connector of the second card assembly.

16. The method of claim 15, wherein the RX signals are each differential signals having two legs each, wherein electrically coupling the conductive traces for carrying the RX signals at the second connector of the first card assembly to the second connector of the second card assembly includes electrically conveying both legs of each of the RX signals from the first connector of the first card assembly to the first connector of the second card assembly.

17. The method of claim 16, wherein electrically coupling the conductive traces for carrying the TX signals excludes electrically coupling any of the conductive traces for carrying the RX signals.

18. The method of claim 17, wherein electrically coupling the conductive traces for carrying the RX signals excludes electrically coupling any of the conductive traces for carrying the TX signals.

19. The method of claim 18, wherein the midplane assembly includes a midplane board having multiple layers, the multiple layers including the first set of midplane circuit board layers and the second set of midplane circuit board layers.

20. The method of claim 18,
wherein the midplane assembly includes a first midplane board and a second midplane board,
wherein electrically coupling the conductive traces for carrying the TX signals is performed by the first midplane board, and
wherein electrically coupling the conductive traces for carrying the RX signals is performed by the second midplane board.
